(19) United States
(12) Patent Application Publication
(10) Pub. No.: US 2025/0149288 A1
(43) Pub. Date: May 8, 2025

(54) Ion Milling Device, and Inspection System

(71) Applicant: Hitachi High-Tech Corporation, Minato-ku, Tokyo (JP)

(72) Inventors: Naohiro FUJITA, Tokyo (JP); Hisayuki TAKASU, Tokyo (JP); Atsushi KAMINO, Tokyo (JP); Hitoshi KAMOSHIDA, Tokyo (JP)

(21) Appl. No.: 18/835,838

(22) PCT Filed: Mar. 1, 2022
(86) PCT No.: PCT/JP2022/008575

§ 371 Date: Aug. 5, 2024

(51) Int. Cl. H01J 37/244; G01N 23/2251; H01J 37/20; H01J 37/305

(52) U.S. Cl. CPC H01J 37/244; G01N 23/2251; H01J 37/20; H01J 37/3053; G01N 2223/401; H01J 2237/20207; H01J 2237/30455

(57) ABSTRACT

An ion milling device includes: a first monitoring mechanism that measures an amount of sputtered particles generated by irradiating a sample with an ion beam; and a second monitoring mechanism that images a processed surface of the sample formed by irradiating the sample with the ion beam, in which processing on the sample ends when a sputtering amount of the sample estimated through measurement by the first monitoring mechanism and a shape of the processed surface image extracted from a picture captured by the second monitoring mechanism satisfy processing end conditions set for the sputtering amount and the shape of the processed surface.

### TECHNICAL FIELD

The present invention relates to an ion milling device and an inspection system.

### BACKGROUND ART

An ion milling device can obtain a smooth processed surface by irradiating a surface or a cross-sectional surface of a sample (such as metal, semiconductor, glass, ceramic, or the like) with a non-convergent ion beam (Ar ion or the like) accelerated at several kV and ejecting atoms of the sample surface without applying stress by a sputtering phenomenon. Such characteristic is excellent for performing smooth processing to observe the surface or the cross-sectional surface of the samples by an electron microscope typified by a scanning electron microscope (SEM) and a transmission electron microscope (TEM).

PTL 1 discloses measurement of a mass of sputtered particles deposited on a crystal resonator from a change in a frequency of an oscillation signal caused by the deposition of the sputtered particles on the crystal resonator by a milling process, and estimation of a film thickness of a redeposition film formed on a sample due to the deposition of the sputtered particles.

### CITATION LIST

### Patent Literature

PTL 1: WO2021/038650A

### SUMMARY OF INVENTION

### Technical Problem

Development of three-dimensional devices in which semiconductor elements are integrated in three dimensions is in progress. There are various three-dimensional devices that have already been in mass production and are still at development stages. For example, flash memories, FinFETs, and gate all around (GAA) FETs in which memory cell arrays are stacked are known. In such devices, high-density, fine grooves or holes with high aspect ratios are provided and insulating films, semiconductor films, or metal films are stacked on the sidewalls of the grooves or the holes to form active elements. To improve a yield in a mass production line of three-dimensional devices that have such internal structures, it is effective to expose the internal structures of the three-dimensional devices and analyze scanning electron microscope (SEM) pictures obtained by imaging the internal fine structures to verify whether desired internal structures have been formed actually.

A cross-sectional milling process by an ion milling device using a non-convergent ion beam has an advantage that an internal structure of a three-dimensional device can be exposed at a high speed, but it is difficult to perform processing with a consistent processed shape.

FIG. 6 is a schematic view illustrating a state while performing a cross-sectional milling process on a sample 1. A configuration of the ion milling device will be described below with reference to FIG. 1. A side view 50 illustrates the sample 1 when viewed from an ion gun that irradiates an ion beam and a top view 51 illustrates the sample 1 when viewed from an imaging device. Holes 52 are viewed in a perspective manner as an example of an internal structure of the sample 1. Since the holes 52 are an internal structure, the holes 52 cannot be viewed from the outside before the cross-sectional milling process.

In the cross-sectional milling process, a cross-sectional surface of the sample is exposed by disposing a shielding plate 3 that shields an ion beam on the sample 1 and performing a milling process on a part of the sample 1 exposed to slightly protrude from an end surface of the shielding plate 3. The intensity of the ion beam is highest at a center (a center of the ion beam) and decreases away from the center of the ion beam in a Gaussian distribution. As a result, a sputtering amount is largest in a region irradiated with the center of the ion beam and decreases away from the center of the ion beam.

Therefore, in the example of FIG. 6, a surface processed by the cross-sectional milling process is formed at an angle inclined with respect to a depth direction of the holes 52 (Y direction). Here, since an intensity distribution of the ion beam changes due to an influence of distance between the ion gun and the sample, an acceleration voltage, a discharge voltage, and a gas flow rate of an ion beam, or the like, it is difficult to irradiate a sample with an ion beam that has a consistently same intensity distribution. Therefore, a variation in the shape of a processed surface to be formed easily occurs for each processed sample.

An internal structure exposed by the cross-sectional milling process is imaged as a SEM picture in the same direction as the top view 51 (hereinafter referred to as a cross-sectional SEM picture) and the picture is analyzed to determine whether the internal structure is formed as a desired configuration. Here, since the surface processed by the cross-sectional milling process is inclined with respect to the depth direction of holes 52, an image of holes 52 in the cross-sectional SEM picture includes distortion caused by the inclination of the processed surface. Although the distortion can be corrected through image processing, the degree of distortion varies depending on the shape of the processed surface. For example, the degree of distortion in an image of holes 52a exposed by a processed surface 53 differs from the degree of distortion in an image of holes 52a exposed by a processed surface 54. When the processed surface is obtained for each cross-sectional milling process, that is, for each processed sample, and distortion correction is performed on the cross-sectional SEM picture according to the inclination of the processed surface, a throughput of inspection deteriorates.

The present invention improves a throughput of inspection by achieving high reproducibility of a processed shape in a cross-sectional milling process.

### Solution to Problem

According to an aspect of the present invention, an ion milling device includes: a sample chamber; an ion gun that discharges a non-convergent ion beam; a sample stage disposed inside the sample chamber and on which the sample is placed so that a part of the sample is exposed from an end surface of a shielding plate that is disposed on the sample to shield the ion beam; a first monitoring mechanism that measures an amount of sputtered particles generated by irradiating the sample with the ion beam; a second monitoring mechanism that images a processed surface of the sample formed by irradiating the sample with the ion beam; and a control unit that ends processing on the sample when a sputtering amount of the sample estimated through measurement by the first monitoring mechanism and a shape of a processed surface image extracted from a picture captured by the second monitoring mechanism satisfy processing end conditions set for the sputtering amount and the shape of the processed surface.

### Advantageous Effects of Invention

High reproducibility of a processed shape in a cross-sectional milling process is achieved. Other tasks and novel characteristics will be apparent from description of the present specification and the appended drawings.

### BRIEF DESCRIPTION OF DRAWINGS

FIG. 1 is a diagram illustrating an entire configuration of an ion milling device.

FIG. 2 is a diagram illustrating a change in a shape of a processed surface over time.

FIG. 3A is a diagram illustrating an example of a processed surface picture.

FIG. 3B is a diagram illustrating an example of a processed surface image.

FIG. 4 is a flowchart illustrating a cross-sectional milling process.

FIG. 5A is a diagram illustrating an overall configuration of an inspection system.

FIG. 5B is a diagram illustrating an example of image processing performed by an image processing unit.

FIG. 6 is a diagram illustrating a problem of the present invention.

### DESCRIPTION OF EMBODIMENTS

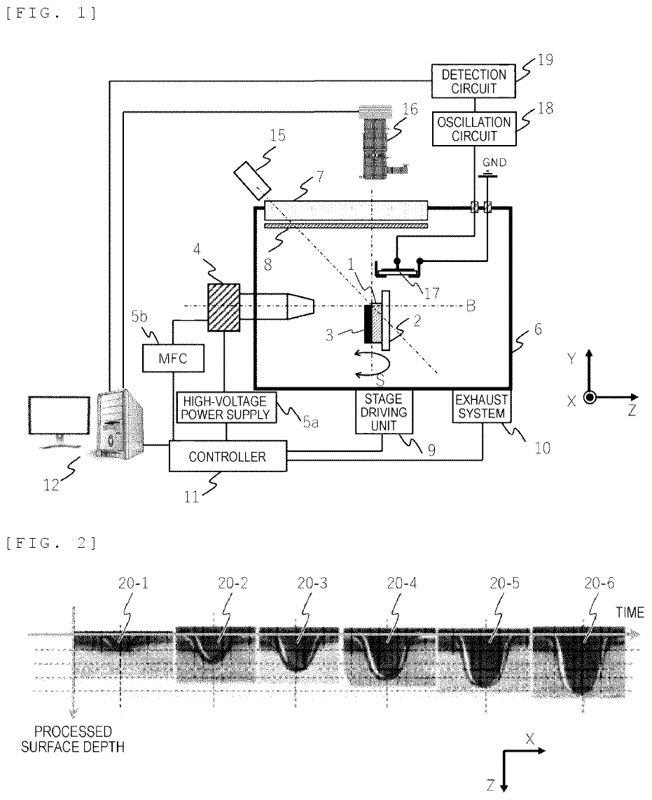

FIG. 1 is a diagram illustrating an entire configuration of an ion milling device. A sample 1 is installed on a sample stage 2 and the sample 1 is irradiated with an ion beam from an ion gun 4. As the ion gun 4, a penning type is used to effectively minimize a size of a structure. In the penning type ion gun, argon ions are generated by colliding electrons produced by penning discharge with argon gas inside the ion gun, and the generated argon ions are accelerated and discharged as the ion beam. Therefore, a discharge voltage for causing penning discharge from the high-voltage power supply 5a and an acceleration voltage for accelerating the argon ions are applied to the ion gun 4, and the argon gas of which a flow rate is controlled by a mass flow controller (MFC) 5b is supplied.

A shielding plate 3 shielding the ion beam irradiated from the ion gun 4 to the sample 1 is disposed on the sample 1 and a part of the sample 1 exposed to protrude from an end surface of the shielding plate 3 is milled with the ion beam (cross-sectional milling). During the cross-sectional milling process, the sample stage 2 is driven by a stage driving unit 9. For example, the stage driving unit 9 performs, on the sample stage 2, a swing operation around a swing axis S set to be orthogonal to an ion beam center B of the ion beam (Y direction) and a sliding operation in a direction orthogonal to the ion beam center B and the swing axis S (X direction). A processed surface can be smoothed through a swing operation of swinging the sample 1 around the swing axis S within a predetermined angle range (a swing angle). A processing width in the X direction can be widened through a sliding operation of moving the sample 1 back and forth around the ion beam center B in the X direction. The milling process is performed inside a sample chamber 6 vacuum-exhausted by an exhaust system 10.

Control of the ion milling device is performed by a computer 12 and a controller 11 which are inclusively referred to as a control unit. The computer 12 sets a milling condition set by a user in the controller 11, performs monitoring of a milling process (which will be described in detail), and changes a control value of the controller 11. The controller 11 controls each configuration (the ion gun 4, the sample stage 2, the exhaust system 10, and the like) of the ion milling device based on the set or changed control value.

The ion milling device includes at least two monitoring mechanisms to monitor a cross-sectional milling process. A first monitoring mechanism is a sensor that estimates a sputtering amount of a sample by the cross-sectional milling process. The first monitoring mechanism includes a crystal resonator 17 disposed near the sample 1, an oscillation circuit 18, and a detection circuit 19. The crystal resonator 17 is for example, a discoid crystal resonator and i preferably provided to be movable inside the sample chamber 6 so that a position or a direction can be adjusted to optimize sensitivity of the monitoring. During the milling process, the oscillation circuit 18 oscillates the crystal resonator 17 to output an oscillation signal, and detects a frequency of the oscillation signal in the detection circuit 19. The frequency f the oscillation signal is changed by adhering the sputtered particles generated through the milling process to the crystal resonator 17 and increasing a mass of the crystal resonator. The phenomenon is used to measure the mass of the sputtered particles deposited on the crystal resonator 17 from a change in the frequency of the oscillation signal. It is possible to estimate the sputtering amount of the sample 1 by the milling process from the mass of the sputtered particles deposited on the crystal resonator 17.

A second monitoring mechanism is an image sensor that monitors a processed shape by the cross-sectional milling process. The second monitoring mechanism includes a light 15 such as an LED provided outside of the sample chamber 6 and an imaging device 16 that enlarges and images the processed shape of the sample 1 by an optical microscope or an electron microscope. Therefore, an observation window 7 is installed on an upper surface of the sample chamber 6 and the processed surface formed by the cross-sectional milling process can be imaged by the imaging device 16 via the observation window 7. To prevent adhering of the sputtered particles on the observation window 7, the inner surface of the observation window 7 is protected by a shutter 8. During a period in which the sample 1 is irradiated with the ion beam, the shutter 8 is closed to prevent adhering of the sputtered particles on the observation window 7. The light 15 illuminates the inside of the sample chamber 6 and the imaging device 16 images a processed surface picture of the sample 1 at a predetermined time interval.

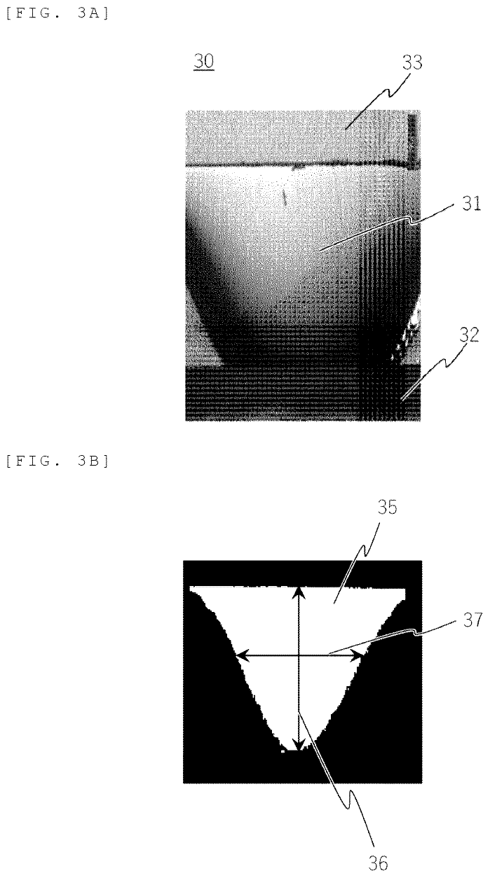

FIG. 2 is a diagram illustrating a change in the shape of a processed surface over time in the cross-sectional milling process with a picture 20 by the imaging device 16. The example is an example in which the sample with no internal structure is subjected to the cross-sectional milling process. It can be known that a processed surface depth (the Z direction) becomes deeper as time passes. On the other hand, a processing depth (the Y direction) cannot be ascertained from an image obtained by imaging the processed surface from above. Accordingly, in the embodiment, monitoring of a sputtering amount is used in addition to monitoring with a picture. When the processed surface shape observed from above and the sputtering amount match desired values, respectively, it can be estimated that a three-dimensional processed surface formed through the cross-sectional milling process is a desired processed surface.

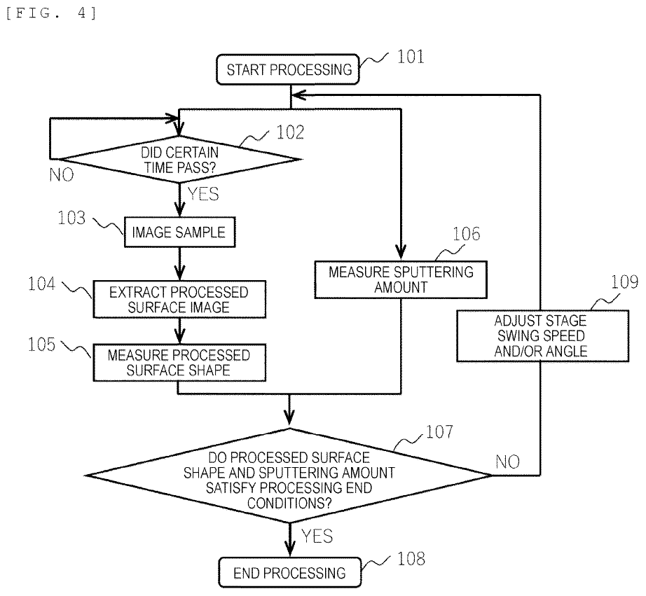

To automatically monitor a change in the processed surface shape observed from the above, as illustrated in FIG. 2, image processing is performed on an obtained processed surface picture. FIG. 3A is a diagram illustrating a processed surface picture 30 enlarged and imaged by an optical microscope. The processed surface picture 30 includes a sample image 31 subjected to the cross-sectional milling process, a sample stage image 32, and a shielding plate image 33. The computer 12 binarizes the processed surface picture 30 to obtain a processed surface image e 35 illustrated in FIG. 3B. In the binarization, the processed surface shape is extracted considering how a shadow shades by the light 15. When a processed surface depth 36 and a half-value width (full width half maximum (FWHM)) 37 are used as representative values indicating the processed surface shape for the determination of the processed surface shape to be described below, the processed surface depth 36 and the half-value width 37 are measured from the processed surface image 35. The computer 12 automatically acquires and measures the processed surface image 35 from the processed surface picture 30.

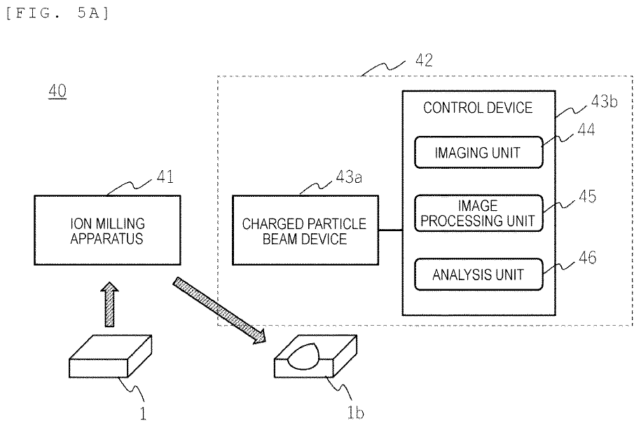

FIG. 4 is a flowchart illustrating a cross-sectional milling process according to the embodiment. The flow is controlled by the computer 12.

Step 101: A user sets a milling condition on the computer 12. The milling condition includes information regarding a desired processed surface shape and processing amount. Specifically, the processed surface shape and the sputtering amount that are processing end conditions are set. A setting method is not particularly limited, and the processed surface image may be registered or a representative value of the processed surface image may be registered according to a method of determining the processed surface shape by the computer 12. For the sputtering amount, a sputtering amount of a sample to be processed may be registered or an expected value of the sputtering amount deposited on the crystal resonator 17 by processing the sample may be registered. After the milling condition is set, the ion milling device starts processing.

Steps 102 and 103: After the processing continues for a certain time, the irradiation of the sample 1 with the ion beam by the ion gun 4 stops, and the imaging device 16 images the sample 1 via the observation window 7 to obtain a processed surface picture of the sample 1.

Step 104: The computer 12 extracts a processed surface image from the processed surface picture.

Step 105: The processed surface depth and the half-value width are measured from the processed surface image. Measurement content in the current step follows a method of determining the processed surface shape and is not limited to the processed surface depth and the half-value width. In addition to or instead of the two representative values, a measured value of the processed surface image may be used.

Step 106: During the cross-sectional milling process, the first monitoring mechanism performs monitoring of the cross-sectional milling process together with the monitoring of the cross-sectional milling process by the second monitoring mechanism in steps 102 to 105. That is, the oscillation circuit 18 oscillates the crystal resonator 17 to output an oscillation signal and detects a frequency of the oscillation signal in the detection circuit 19. The computer 12 estimates a sputtering amount of the sample 1 from a change in the frequency of the oscillation signal detected by the detection circuit 19. As an estimation method, the sputtering amount of the sample 1 may be estimated form the sputtering amount deposited on the crystal resonator 17 or the sputtering amount deposited on the crystal resonator 17 may be considered as a sputtering amount of the sample 1.

Step 107: The processing ends when the measured processed surface shape and the measured sputtering amount satisfy the processing end conditions (step 108).

When the processing end conditions are not satisfied, the process transitions to step 109. For example, it is assumed that, with respect to the processed surface shape and the sputtering amount that are set as the processing end conditions in step 101, the processed end conditions are satisfied when each of the measured processed surface shape and sputtering amount is included in a predetermined error range, and the processing ends.

Step 109: The computer 12 adjusts a swing speed and/or a swing angle of the sample stage 2 as necessary. The computer 12 stores a method of adjusting the swing speed and the swing angle of the sample stage 2 in correspondence to the processed surface shape in advance and adjusts a method of driving the sample stage 2 according to the processed surface shape measured in step 105. A user acquires time change information of the processed surface shape and time change information of the sputtering amount as illustrated in FIG. 2 from various sample stage driving conditions in advance and sets a method of adjusting driving of the sample stage 2 based on the information. The computer 12 stores an ideal processed surface shape and sputtering amount according to a time passed from start of the processing to estimate the gap from the processed surface in three dimensions currently and can adjust a method of driving the sample stage, for example, so that processing in the Z direction (a processed surface depth direction) is more proceeded or the processing in the Y direction (a processing depth direction) is more proceeded.

In a normal ion milling device, the processing end conditions are set according to the time passed from the start of the processing, and the processing ends after performing processing for a predetermined time under a first set milling condition. On the other hand, in the ion milling device according to the embodiment, reproducibility of the processing of the sample in three dimensions can be improved by monitoring the processed surface shape and the sputtering amount and performing feedback in milling process conditions.

The flowchart of FIG. 4 can be modified variously. For example, the certain time of step 102 may be set by the user or may be set by the device. A frequency at which the sample is imaged may be changed according to the sputtering amount measured in step 106.

The determination of the processing end conditions for the processed surface shape is not limited to comparison of the representative value of the processed surface shape. For example, in step 105, a contour of the processed surface image can be modeled. The computer 12 can store a shape model of the contour of an ideal processed surface shape according to the time passed from the start of the processing and compare the shape model of the contour of the ideal processed surface shape with a shape model of a contour of the extracted processed surface image for determination. The computer 12 may store a trained model for which the state of the processed surface shape is trained and determine whether the processing end conditions are satisfied by the trained model. Here, the measurement process of step 105 can be omitted. The trained model here can include a trained model that determines whether the end conditions are satisfied and a trained model that determines a most similar processed surface shape in a time series of the processed surface shape illustrated in FIG. 2.

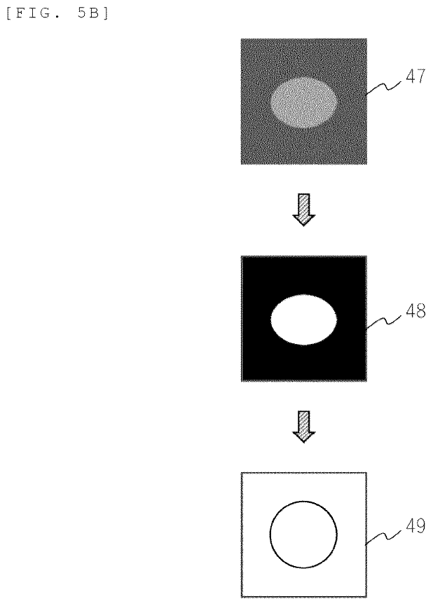

FIG. 5A is a diagram illustrating an inspection system using the above-described ion milling device. An inspection system 40 includes an ion milling device 41 and an inspection device 42. The inspection device 42 includes a charged particle beam device 43a and a control device 43b. The ion milling device 41 performs processing to expose a cross section of the sample 1, and the inspection device 42 images a processed sample 1b by the charged particle beam device 43a and analyzes whether the internal structure of the sample 1 is appropriately formed from the cross-sectional picture of the processed sample 1b.

For example, a scanning electron microscope is applied to the charged particle beam device 43a. The control device 43b is configured as a computer and can realize a predetermined function by executing a program. Here, as a function related to the inspection, an imaging unit 44, an image processing unit 45, and an analysis unit 46 are indicated. The imaging unit 44 controls the charged particle beam device 43a to image a cross-sectional picture of the processed sample 1b. The image processing unit 45 performs image processing on the imaged cross-sectional picture of the processed sample 1b. The analysis unit 46 analyzes whether a desired internal structure is formed in the sample 1 from the cross-sectional image subjected to predetermined image processing.

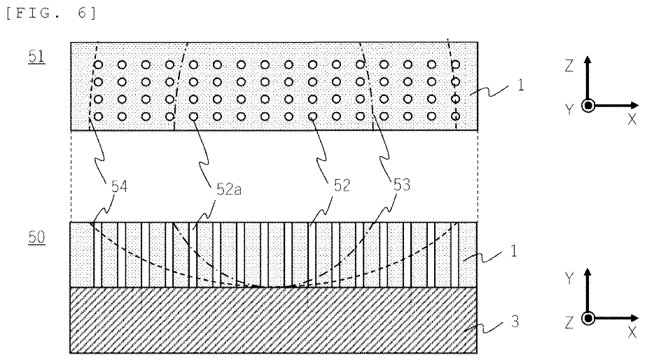

FIG. 5B is a diagram illustrating an example of image processing performed by the image processing unit 45. A pattern of the holes (internal structure) illustrated in FIG. 6 is shown in a cross-sectional picture 47 of the processed sample 1b imaged by the charged particle beam device 43a. As a processed surface in the cross-sectional milling process is inclined in the cross-sectional picture 47, a pattern image is distorted. The image processing unit 45 obtains a correction pattern image 49 by binarizing the cross-sectional picture 47, extracting a pattern image 48, and correcting distortion by the inclination of the processed surface.

In the inspection system according to the embodiment, a variation in the three-dimensional processed surface of the processed sample 1b is restricted within a predetermined range. Therefore, the image processing unit 45 is not required to change a correction method or a correction amount of the correction pattern image 49 for each processed sample 1b and can execute the same correction regardless of the processed sample 1b. Accordingly, it is possible to improve a throughput of the inspection.

The present invention is not limited to the foregoing embodiment and includes various modifications. For example, the foregoing embodiment has been described in detail to easily understand the present invention and does not necessarily include all the described configurations. Some of configurations according to a certain embodiment can be substituted with configurations according to other embodiments and configurations according to the other embodiments may be added to configurations of a certain embodiment. Other configurations can be added to, deleted from, or substituted with some of configurations of each embodiment. Each of the foregoing configurations, functions, processing units, processing means, and the like may be implemented with hardware, for example, by designing some or all of the configurations, functions, processing units, processing means, and the like with an integrated circuit. Each of the foregoing configurations, functions, and the like may be implemented with software by a processor interpreting and executing a program for implementing each function. Information such as a program, a table, a file, or the like implementing each function can be stored on a storage device such as a memory, a hard disk, and a solid state drive (SSD) or any of other recording media.

### REFERENCE SIGNS LIST

1: sample
1b: processed sample
2: sample stage
3: shielding plate
4: ion gun
5a: high-voltage power supply
5b: MFC
6: sample chamber
7: observation window
8: shutter
9: stage driving unit
10: exhaust system
11: controller
12: computer
15: light
16: imaging device
17: crystal resonator
18: oscillation circuit
19: detection circuit
20: picture
30: processed surface picture
31: sample image
32: sample stage image
33: shielding plate image
35: processed surface image
36: processed surface depth
37: half-value width
41: ion milling device
42: inspection device
43a: charged particle beam device
43b: control device
44: imaging unit
45: image processing unit
46: analysis unit
47: cross-sectional picture
48: pattern image
49: correction pattern image
50: side view
51: top view
52: hole
53, 54: processed surface

1.-9. (canceled)

10. An ion milling device comprising:
a sample chamber;
an ion gun that discharges a non-convergent ion beam;
a sample stage disposed inside the sample chamber and on which the sample is placed so that a part of the sample is exposed from an end surface of a shielding plate that is disposed on the sample to shield the ion beam;
a first monitoring mechanism that measures an amount of sputtered particles generated by irradiating the sample with the ion beam;
a second monitoring mechanism that includes an imaging device that is disposed outside of the sample chamber and images a processed surface of the sample via an observation window provided in the sample chamber, so that an optical axis of the imaging device is disposed to be orthogonal to an ion beam center of the ion beam, and that images a processed surface of the sample formed by irradiating the sample with the ion beam; and
a control unit that ends processing on the sample when a sputtering amount of the sample estimated through measurement by the first monitoring mechanism and a shape of a processed surface image extracted from a picture imaged by the second monitoring mechanism satisfy processing end conditions set for the sputtering amount and the shape of the processed surface.

11. The ion milling device according to claim 10, further comprising:
a stage driving unit that performs a swing operation to swing the sample stage around a swing axis orthogonal to an ion beam center of the ion beam at a predetermined swing angle, wherein
the control unit adjusts a swing speed and/or a swing angle of the swing operation of the sample stage by the stage driving unit when the sputtering amount of the sample estimated through measurement by the first monitoring mechanism and the shape of the processed surface image extracted from the picture imaged by the second monitoring mechanism do not satisfy the processing end conditions.

12. The ion milling device according to claim 10, wherein
the first monitoring mechanism includes a crystal resonator disposed inside the sample chamber, an oscillation circuit oscillating the crystal resonator and outputting an oscillation signal, and a detection circuit detecting a frequency of the oscillation signal, and
the control unit estimates the sputtering amount of the sample from a mass of sputtered particles deposited on the crystal resonator measured from a change in the frequency of the oscillation signal.

13. The ion milling device according to claim 10, wherein the imaging device of the second monitoring mechanism images the processed surface of the sample at a predetermined time interval.

14. The ion milling device according to claim 10, wherein the control unit measures a processed surface depth and a half-value width of the processed surface image and determines whether the processing end conditions are satisfied based on the processed surface depth and the half-value width of the processed surface image.

15. An inspection system that inspects a predetermined internal structure of a sample, the inspection system comprising:
the ion milling device according to claim 10; and
an inspection device that inspects an internal structure of a processed sample processed by the ion milling device, wherein
the inspection device includes
a charged particle beam device,
an imaging unit that acquires a cross-sectional picture by imaging a processed surface of the processed sample by the charged particle beam device,
an image processing unit that extracts a pattern image of a predetermined internal structure from the cross-sectional picture, performs distortion correction on the pattern image, and outputs a correction pattern image, and
an analysis unit that analyzes the correction pattern image of the predetermined internal structure output by the image processing unit, and
the distortion correction is performed to correct distortion by inclination of the processed surface of the processed sample and the image processing unit performs identical distortion correction on each of the pattern images extracted from a plurality of processed samples processed by the ion milling device to inspect the predetermined internal structure.

16. An ion milling device comprising:
a sample chamber;
an ion gun that discharges a non-convergent ion beam;
a sample stage disposed inside the sample chamber and on which the sample is placed so that a part of the sample is exposed from an end surface of a shielding plate that is disposed on the sample to shield the ion beam;
a first monitoring mechanism that measures an amount of sputtered particles generated by irradiating the sample with the ion beam;
a second monitoring mechanism that images a processed surface of the sample formed by irradiating the sample with the ion beam; and
a control unit that ends processing on the sample when a sputtering amount of the sample estimated through measurement by the first monitoring mechanism and a shape of a processed surface image extracted from a picture imaged by the second monitoring mechanism satisfy processing end conditions set for the sputtering amount and the shape of the processed surface, wherein
the control unit measures a processed surface depth and a half-value width of the processed surface image and determines whether the processing end conditions are satisfied based on the processed surface depth and the half-value width of the processed surface image.

17. An inspection system that inspects a predetermined internal structure of a sample, the inspection system comprising:
an ion milling device; and
an inspection device that inspects an internal structure of a processed sample processed by the ion milling device, wherein
the ion milling device includes
a sample chamber,
an ion gun that discharges a non-convergent ion beam;
a sample stage disposed inside the sample chamber and on which the sample is placed so that a part of the sample is exposed from an end surface of a shielding plate that is disposed on the sample to shield the ion beam,
a first monitoring mechanism that measures an amount of sputtered particles generated by irradiating the sample with the ion beam,
a second monitoring mechanism that images a processed surface of the sample formed by irradiating the sample with the ion beam, and
a control unit that ends processing on the sample when a sputtering amount of the sample estimated through measurement by the first monitoring mechanism and a shape of a processed surface image extracted from a picture imaged by the second monitoring mechanism satisfy processing end conditions set for the sputtering amount and the shape of the processed surface,
the inspection device includes
a charged particle beam device,
an imaging unit that acquires a cross-sectional picture by imaging a processed surface of the processed sample by the charged particle beam device,
an image processing unit that extracts a pattern image of a predetermined internal structure from the cross-sectional picture, performs distortion correction on the pattern image, and outputs a correction pattern image, and
an analysis unit that analyzes the correction pattern image of the predetermined internal structure output by the image processing unit, and
the distortion correction is performed to correct distortion by inclination of the processed surface of the processed sample and the image processing unit performs identical distortion correction on each of the pattern images extracted from a plurality of processed samples processed by the ion milling device to inspect the predetermined internal structure.
